(19) United States
(12) Patent Application Publication
(10) Pub. No.: US 2019/0275763 A1
(43) Pub. Date: Sep. 12, 2019

(54) MOLD RELEASE SHEET FOR SEMICONDUCTOR COMPRESSION MOLDING AND SEMICONDUCTOR PACKAGE WHICH IS MOLDED USING SAME

(71) Applicant: HITACHI CHEMICAL COMPANY, LTD., Tokyo (JP)

(72) Inventors: Masahiko SUZUKI, Chiyoda-ku, Tokyo (JP); Ryo TAMURA, Chiyoda-ku, Tokyo (JP); Takuji IKEYA, Chiyoda-ku, Tokyo (JP)

(21) Appl. No.: 16/302,994

(22) PCT Filed: May 20, 2016
(86) PCT No.: PCT/JP2016/065070

§ 371 Date: Nov. 19, 2018

(51) Int. Cl. B32B 7/06; H01L 21/56; H01L 23/29; B32B 27/36; B32B 27/14

(52) U.S. Cl. CPC B32B 7/06; H01L 21/566; H01L 23/293; B32B 2264/0235; B32B 27/14; B32B 2264/025; B32B 2264/0257; B32B 27/36

(57) ABSTRACT

A release sheet for semiconductor compression molding includes a release layer that includes particles, and a base layer. The content ratio of the particles in the release layer is from 5% by volume to 65% by volume.

### TECHNICAL FIELD

The invention relates to a release sheet for semiconductor compression molding, and a semiconductor package molded using the release sheet.

### BACKGROUND ART

Semiconductor chips are usually sealed with a resin for the purpose of shielding from the external air and protection, and are mounted on substrates as molded products referred to as packages. The molded products have conventionally been formed as package molded products that each carry a single chip and that are mutually connected via runners, which are flow paths for a sealing resin. In this case, releasability of the molding products from a mold is imparted based on, for example, the structure of the mold or the addition of a release agent to the sealing resin.

Packages such as ball grid array (BGA) packages, quad flat non-leaded (QFN) packages and wafer level chip size packages (WL-CSP) have increasingly been used due to, for example, demand for downsizing of packages and provision of multiple pins. In the QFN process, resin-made release films are used in order to ensure the presence of the standoff and in order to prevent the occurrence of burrs of the sealing material at terminals, and, in the BGA process and the WL-CSP process, resin-made release films are used in order to improve the releasability of the package from the mold (see, for example, Japanese Patent Application Laid-open (JP-A) No. 2002-158242). Molding methods using a release film, such as those described above, are referred to as “film-assisted molding”.

### SUMMARY OF INVENTION

### Technical Problem

By using the aforementioned release film, it can be made possible to easily release a sealing material of a semiconductor package from a mold when the semiconductor package is molded using a resin. However, there is a possibility that the outer appearance of the surface of the molded package may be non-uniform and may have a flow mark resulting from flow of the sealing material, or a possibility that a release film material contaminates the surface of the molded semiconductor package.

Further, as the molding method used in the BGA process and the WL-CSP process has been changed from a conventional transfer molding method to a compression molding method, the size per one shot has increased, and the demanded level has been elevated with respect to, for example, the uniformity of the outer appearance of the surface of the molded package and the flow mark resulting from flow of the sealing material.

According to one aspect of the invention, a release sheet for semiconductor compression molding is provided which enables easy release of the sealing material from the mold without damaging the semiconductor package when the semiconductor package is resin-molded using a compression molding method, has excellent uniformity of the outer appearance of the surface of the molded semiconductor package, and enables reduction of contamination of the surface of the molded semiconductor package caused by a release sheet material. According to another aspect of the invention, a semiconductor package is provided that is molded using the release sheet for semiconductor compression molding.

### Solution to Problem

The invention includes the following aspects.

<1> A release sheet for semiconductor compression molding, the release sheet comprising:

a release layer that includes particles; and

a base layer,

wherein a content ratio of the particles in the release layer is from 5% by volume to 65% by volume.

<2> The release sheet for semiconductor compression molding according to <1>, wherein the particles have an average particle diameter of from 1 μm to 55 μm.

<3> The release sheet for semiconductor compression molding according to <1> or <2>, wherein the particles are resin particles.

<4> The release sheet for semiconductor compression molding according to <3>, wherein the resin particles comprise at least one selected from the group consisting of an acrylic resin, a polyolefin resin, a polystyrene resin, a polyacrylonitrile resin, and a silicone resin.

<5> The release sheet for semiconductor compression molding according to any one of <1> to <4>, wherein the base layer is a polyester film.

<6> A semiconductor package molded using the release sheet for semiconductor compression molding according to any one of <1> to <5>.

### Effects of Invention

According to one aspect of the invention, a release sheet for semiconductor compression molding is provided which enables easy release of the sealing material from the mold without damaging the semiconductor package when the semiconductor package is molded using a compression molding method, has excellent uniformity of the outer appearance of the surface of the molded semiconductor package, and enables reduction of contamination of the surface of the molded semiconductor package caused by a release sheet material. According to another aspect of the invention, a semiconductor package is provided that is molded using the release sheet for semiconductor compression molding.

### DESCRIPTION OF EMBODIMENTS

Embodiments of the invention are described in detail below. However, the invention is not limited to the below-described embodiments.

In the present specification, numerical ranges expressed using “to” each indicate a range that includes the numerical values noted before and after “to” as the minimum value and the maximum value, respectively.

When there are plural substances in the composition that correspond to a particular component, the amount of the component in the composition indicated in the specification refers to the total amount of the plural substances present in the composition unless specified otherwise.

The scope of the term “step” as used herein includes not only an independent step, but also a step that is not clearly separated from another step, as long as the intended effect of the step of interest is exerted.

The scope of the terms “layer” and “film” as used herein includes not only a structure that covers the entire face, but also a structure that covers a part of the face, when observed in a plan view.

In the specification, the term “(meth)acryl” refers to at least one of “acryl” or “methacryl”, and the term “(meth)acrylate” refers to at least one of “acrylate” or “methacrylate”.

When numerical ranges having stepwise changed breadths are described in the specification, the upper limit value or lower limit value of one described numerical range may be replaced by the upper limit value or lower limit value of another numerical range in the stepwise sequence. Further, the upper limit value or lower limit value of any numerical range described in the specification may be replaced by a numerical value indicated in the Examples.

In the specification, the average thickness (also referred to as the average value of the thickness) of a layer or a film refers to a numerical value that is obtained as an arithmetic mean value of thicknesses measured at 5 positions on the layer or film to be measured.

The thickness of the layer or film can be measured using, for example, a micrometer. The measurement is performed using a micrometer when the thickness of the layer or film can be directly measured. When the thickness of one layer or the total thickness of plural layers is to be measured, the measurement may be performed by observing a cross-section of the release sheet using an electron microscope.

In the specification, the average particle diameter is obtained as a particle diameter (50% D) at which a cumulative volume accumulated from the smaller particle diameter side reaches 50% in a cumulative-volume-based particle size distribution curve obtained using a laser diffraction/scattering particle size distribution measurement method. The measurement may be performed, for example, by using a particle diameter distribution measurement instrument that utilizes a laser light scattering method (for example, SALD-3000 available from Shimadzu Corporation).

<Release Sheet for Semiconductor Compression Molding>

The release sheet for semiconductor compression molding (hereinafter also referred to as the “release sheet”) includes a release layer that includes particles, and a base layer, and the content ratio of the particles in the release layer is from 5% by volume to 65% by volume.

More specifically, the release sheet has a double layer structure in which a base layer configured to contact a mold to be used in resin molding of a semiconductor package is provided, and in which a release layer configured to contact the semiconductor package to be molded is provided on one face of the base layer.

The release sheet, having the aforementioned configuration, enables easy release of the sealing material from the mold without damaging the semiconductor package when the semiconductor package is molded by compression molding, improves the uniformity of the outer appearance of the surface of the molded semiconductor package, and enables reduction of contamination of the surface of the molded semiconductor package due to a release sheet material. The reason therefor is not clear but is presumed to be as follows.

When a conventional release sheet is used in molding of a semiconductor package, the release sheet is required to have a shape changeability that sufficiently conforms to the shape of the mold from the viewpoint of reducing the occurrence of shape defects, such as wrinkles, of the molded semiconductor package. The release sheet is also required to have sufficient releasability from the semiconductor package since an excessive force applied at the time of removing the semiconductor package from the mold tends to break the semiconductor package.

It is conceivable that the release sheet according to the present specification has an improved releasability from the molded semiconductor package while maintaining the shape changeability to conform to the mold, due to the inclusion of two layers having mutually different functions, which are the release layer having excellent releasability from the sealing resin (such as an epoxy resin) for a semiconductor package, and the base layer having excellent shape changeability to conform to the mold.

It is also conceivable that the inclusion of particles at a specified content ratio in the release layer in the release sheet according to the present specification causes the release layer to have a rough outer surface (the surface that faces the semiconductor package) and therefore imparts roughness to a surface of the semiconductor package to be molded, and that the roughness of the surface of the semiconductor package reduces flow marks resulting from flow of the sealing material and improves the uniformity of the outer appearance of the surface of the package. Further, the particle diameter, shape and the like of the particles can easily be selected, and it becomes easy to adjust the degree of variations in roughness on the outer surface of the release layer. Moreover, it is conceivable that, when the particles are resin particles, the resin particles do not easily drop out of the release layer owing to the high adhesion to other components contained in the release layer, as a result of which contamination of the semiconductor package can be reduced.

[Release Layer that Includes Particles]

The release sheet includes a release layer that includes particles (hereinafter may be referred to as “specific release layer”), and the content ratio of particles in the specific release layer is from 5% by volume to 65% by volume.

(Particles)

The type of the particles contained in the release layer is not particularly limited, and inorganic particles and organic particles are both usable. Examples of the material of the inorganic particles include alumina, aluminum hydroxide, boron nitride, silicon oxide and graphite. Examples of the organic particles include resin particles.

The particles are preferably resin particles from the viewpoint of improving adhesiveness to other components contained in the release layer. When the particles are resin particles, the adhesiveness between the particles and the other components contained in the release layer improves, the particles are less likely to drop out of the release layer, and the contamination of the semiconductor package is reduced.

The resin particles preferably include at least one selected from the group consisting of an acrylic resin, a polyolefin resin, a polystyrene resin, a polyacrylonitrile resin, and a silicone resin. From the viewpoint of releasability from the semiconductor package, the resin particles more preferably include at least one selected from an acrylic resin, a polystyrene resin, or a polyacrylonitrile resin.

The resin particles are preferably insoluble or scarcely soluble in an organic solvent usable for the preparation of a composition for forming the release layer (for example, toluene, methyl ethyl ketone, or ethyl acetate) from the viewpoint of uniformity of the outer appearance of the surface of the package. Being insoluble or scarcely soluble in organic solvent means that the gel fraction is 97% or higher after the resin particles are dispersed in an organic solvent, such as toluene, and stored at 50° C. for 24 hours in a gel fraction test according to Japanese Industrial Standards (JIS) K6769 (2013) or ISO 15875-2 (2003).

Examples of the acrylic resin include a (co)polymer of a (meth)acrylic monomer, and specific examples thereof include (meth)acrylic acid resins, and (meth)acrylic ester resins (for example, alkyl (meth)acrylate resins and dimethylaminoethyl (meth)acrylate resins).

Examples of the (meth)acrylic monomer include methyl acrylate, methyl methacrylate, ethyl acrylate, ethyl methacrylate, n-propyl acrylate, n-propyl methacrylate, isopropyl acrylate, isopropyl methacrylate, n-butyl acrylate, n-butyl methacrylate, isobutyl acrylate, isobutyl methacrylate, sec-butyl acrylate, sec-butyl methacrylate, tert-butyl acrylate, tert-butyl methacrylate, pentyl acrylate, pentyl methacrylate, hexyl acrylate, hexyl methacrylate, heptyl acrylate, heptyl methacrylate, 2-ethylhexyl acrylate, 2-ethylhexyl methacrylate, octyl acrylate, octyl methacrylate, nonyl acrylate, nonyl methacrylate, decyl acrylate, decyl methacrylate, dodecyl acrylate, dodecyl methacrylate, tetradecyl acrylate, tetradecyl methacrylate, hexadeyl acrylate, hexadecyl methacrylate, octadecyl acrylate, octadecyl methacrylate, eicosyl acrylate, eicosyl methacrylate, docosyl acrylate, docosyl methacrylate, cyclopentyl acrylate, cyclopentyl methacrylate, cyclohexyl acrylate, cyclohexyl methacrylate, cycloheptyl acrylate, cycloheptyl methacrylate, benzyl acrylate, benzyl methacrylate, phenyl acrylate, phenyl methacrylate, methoxyethyl acrylate, methoxyethyl methacrylate, dimethylaminoethyl acrylate, dimethylaminoethyl methacrylate, diethylaminoethyl acrylate, diethylaminoethyl methacrylate, dimethylaminopropyl acrylate, dimethylaminopropyl methacrylate, 2-chloroethyl acrylate, 2-chloroethyl methacrylate, 2-fluroroethyl acrylate, 2-fluoroethyl methacrylate, styrene, α-methylstyrene, cyclohexylmaleimide, dicyclopentanyl acrylate, dicyclopentanyl methacrylate, vinyltoluene, vinyl chloride, vinyl acetate, N-vinylpyrrolidone, butadiene, isoprene and chloroprene. These may be used singly or in combination of two or more thereof.

The polyolefin resin is not particularly limited as long as it is a (co)polymer of an olefin monomer or an alkene monomer. Specific examples thereof include polyethylene, polypropylene and polymethylpentene.

Examples of the polystyrene resin include a (co)polymer of styrene or a styrene derivative. Examples of the styrene derivative include: alkyl-substituted styrenes, which have an alkyl chain, such as α-methylstyrene, 4-methylstyrene, 2-methylstyrene, 3-methyl styrene, 2-ethyl styrene, 3-ethyl styrene, and 4-ethyl styrene; halogen-substituted styrenes such as 2-chlorostyene, 3-chlorostyrene, and 4-chlorostyene; fluoro-substituted styrenes such as 4-fluorostyrene and 2,5-difluorostyrene; and vinylnaphthalene.

Examples of the polyacrylonitrile resin include a (co)polymer of an acrylonitrile monomer.

From the viewpoint of reducing a dissolution property of the resin particles in an organic solvent, the resin contained in the resin particles is preferably a crosslinked resin.

The average particle diameter of the particles is preferably from 1 μm to 55 μm. When the average particle diameter of the particles is 1 μm or more, irregularities can sufficiently be formed on the surface of the specific release layer, and there is a tendency that the uniformity of the outer appearance of the surface of the molded semiconductor package is improved, and that the flow marks resulting from flow of the sealing material is reduced. An average particle diameter of the particles of 55 μm or less is preferable in terms of cost since there would be no need to adopt an excessively large thickness for the specific release layer in order to fix the particles in the specific release layer.

The upper limit value of the average particle diameter of the particles is preferably 55 μm, and more preferably 50 μm, from the viewpoint of the outer appearance of the surface of the semiconductor package. The lower limit value of the average particle diameter of the particles is more preferably 3 μm, and still more preferably 10 μm, from the viewpoint of cost.

The shape of the particles contained in the specific release layer is not particularly limited, and may be any of a spherical shape, an ellipsoidal shape or an indefinite shape, for example.

Specific examples of the particles include TAFTIC series products, for example, TAFTIC FH-S010 (available from Toyobo Co., Ltd.), which is an acrylic resin particle.

The content ratio of particles in the specific resin layer is 5% by volume to 65% by volume.

When the content ratio of particles is 5% by volume or more, irregularities can sufficiently be formed on the surface of the specific release layer, and there is a tendency that the uniformity of the outer appearance of the surface of the molded semiconductor package improves, and that the effect in terms of reducing the flow marks resulting from flow of the sealing material is sufficiently obtained. From these viewpoints, the lower limit value of the content ratio of particles is preferably 10% by volume, and more preferably 20% by volume.

When the content ratio of particles is 65% by volume or less, there is a tendency that the particles are easily fixed in the after-mentioned resin component in the specific release layer, that the possibility of particle drop-off is reduced to reduce the contamination of the surface of the molded semiconductor package, and that the content ratio is economically preferable. From these viewpoints, the upper limit value of the content ratio of particles is preferably 60% by volume, and more preferably 50% by volume.

The content ratio of particles can be obtained as a proportion of particles in a unit area, for example, by observing a cross-section of the specific release layer of the release sheet under a scanning electron microscope (SEM). More specifically, the content ratio can be obtained according to the following method.

First, a cross-section of the specific release layer is observed under a SEM, and the number and particle diameters of the particles contained in an arbitrary area (hereinafter also referred to as the “given area”) in the cross-section are measured. Then, an arbitrary volume (hereinafter also referred to as the “given volume”) is set based on the given area, and the number of particles contained in the given volume is calculated. Further, the volume per one particle is calculated based on the particle diameters of the particles. From the number of particles and the volume per one particle thus calculated, the total volume of the particles contained in the given volume is calculated, and divided by the given volume, whereby the volume content ratio of the particles contained in the specific release layer can be calculated.

In another method, the mass (Wc) of the specific release layer at 25° C. is measured, the specific release layer is dissolved in an organic solvent such as toluene, and the mass (Wf) of the remaining particles at 25° C. is measured. Then, the specific gravity (df) of the particles at 25° C. is measured using an electron specific gravity meter or a pycnometer. Then, the specific gravity (dc) of the specific release layer at 25° C. is measured in the same manner. Thereafter, the volume (Vc) of the specific release layer and the volume (Vf) of the remaining particles are measured, and the volume of the remaining particles is divided by the volume of the specific release layer as indicated in Equations (1), thereby obtaining a volume ratio (Vr) of the particles.

Vc=Wc/dc

Vf=Wf/df

Vr=Vf/Vc (Equations 1)

Vc: Volume of Release Layer (cm³)

Wc: Mass of Release Layer (g)

dc: Specific Gravity of Release Layer (g/cm³)

Vf: Volume of Particles (cm³)

Wf: Mass of Particles (g)

df: Specific Gravity of Particles (g/cm³)

Vr: Volume Ratio of Particles

The specific release layer in the present measurement method may be a layer that has been peeled from the release sheet, or may be a layer that has been separately prepared for the measurement method.

(Resin Component of Specific Release Layer)

The specific release layer may further include a resin component. The inclusion of a resin component allows for fixation of the particles in the specific release layer.

The resin component in the specific release layer is not particularly limited. The resin component is preferably an acrylic resin or a silicone resin, and more preferably a crosslinked acrylic resin (hereinafter also referred to as a “crosslinked acrylic copolymer”), from the viewpoints of, for example, releasability from the semiconductor package and heat resistance.

The acrylic resin is preferably an acrylic copolymer obtained by copolymerization of a low glass transition temperature (Tg) monomer, such as butyl acrylate, ethyl acrylate or 2-ethylhexyl acrylate, as a main monomer and a functional group monomer such as an acrylic acid, methacrylic acid, hydroxyethyl methacrylate, hydroxyethyl acrylate, acrylamide or acrylonitrile. The crosslinked acrylic copolymer can be produced by crosslinking the aforementioned monomers with a crosslinking agent.

The crosslinking agent used for producing the crosslinked acrylic copolymer may be a known crosslinking agent such as an isocyanate compound, a melamine compound or an epoxy compound. The crosslinking agent is more preferably a polyfunctional crosslinking agent such as trifunctional or tetrafunctional, in order to form a mesh structure gently spreading in the acrylic resin.

The crosslinked acrylic copolymer that is produced using a crosslinking agent such as those exemplified above has a gently-spreading mesh structure. Therefore, when the crosslinked acrylic polymer is used as a resin component in the specific release layer, the stretchability of the specific release layer improves to reduce inhibition of stretching property of the base layer, as a result of which the shape changeability of the release sheet to conform to the mold at the time of compression molding improves.

From these viewpoints, the amount of the crosslinking agent used in the production of the crosslinked acrylic copolymer is preferably from 3 parts by mass to 100 parts by mass, and more preferably from 5 parts by mass to 70 parts by mass, with respect to 100 parts by mass of the acrylic copolymer. When the amount of the crosslinking agent is 3 parts by mass or more, the strength of the resin components is ensured, and, therefore, contamination is prevented. When the amount of the crosslinking agent is 100 parts by mass or less, the flexibility of the crosslinked acrylic copolymer improves, thereby improving the stretchability of the release layer.

(Other Components)

As far as the effects according to the invention are not impaired, the specific release layer may further include at least one of a solvent, an anchoring improver, a crosslinking enhancer, an antistatic agent, a colorant or the like, if necessary.

(Thickness of Specific Release Layer)

The thickness of the specific release layer is not particularly limited, and may be set, as appropriate, in consideration of the balance with the average particle diameter of the particles to be used. The thickness of the specific release layer is preferably from 0.1 μm to 100 μm, and more preferably from 1 μm to 50 μm.

When the thickness of the specific release layer is excessively smaller than the average particle diameter of the particles to be used, the particles are difficult to fix in the specific release layer, and the possibility of drop-off of the particles increases, which may cause contamination of the surface of the molded semiconductor package. When the thickness of the specific release layer is excessively larger than the average particle diameter of the particles to be used, it becomes difficult to form sufficient irregularities on the surface of the specific release layer, and there is a possibility that the effect in terms of improving the uniformity of the outer appearance of the surface of the molded semiconductor package, the effect in terms of reducing the flow marks resulting from flow of the sealing material, and the like may not be obtained sufficiently. The excessively large thickness of the specific release layer is also economically disadvantageous.

The thickness of the specific release layer in the present specification refers to a dry thickness, and may be obtained by measuring the specific release layer of the release sheet using the aforementioned method for measuring a layer thickness.

(Surface Roughness of Specific Release Layer)

The outer surface (the side opposite from a side that faces the base layer) of the specific release layer preferably has irregularities. The surface roughness of the specific release layer may be assessed by an arithmetic mean roughness (Ra) or a ten-point mean roughness (Rz).

The arithmetic mean roughness (Ra) and the ten-point mean roughness (Rz) may each be obtained, for example, by analyzing a measurement result using JIS B0601 (2013) or ISO 4287 (1997), the measurement result being obtained using a surface roughness measuring instrument (for example, model SE-3500 available from Kosaka Laboratory Ltd.) in a condition including a stylus tip diameter of 2 μm, a feed velocity of 0.5 mm/s and a scanning distance of 8 mm. From the viewpoint of the uniformity of the outer appearance of the package surface, the arithmetic mean roughness (Ra) of the specific release layer is preferably from 0.5 μm to 5 μm, and the ten-point mean roughness (Rz) of the specific release layer is preferably from 5 μm to 50 μm.

The surface roughness of the specific release layer can be adjusted to be within the aforementioned ranges by adjusting the average particle diameter of the particles and the thickness of the specific release layer.

[Base Layer]

The release sheet includes a base layer. The base layer is not particularly limited, and may be selected, as appropriate, from resin-containing base layers used in the present technical field. It is preferable to use a resin-containing base layer having excellent stretchability from the viewpoint of improving the shape changeability of the release sheet to conform to the shape of the mold.

Considering that the molding of the sealing material is performed at high temperature (about 100° C. to about 200° C.), the base layer preferably has a thermal resistance beyond such a temperature. In order to reduce the occurrence of, for example, wrinkles of the sealing resin or breakage of the release sheet at the time of placing the release sheet on the mold and at the time of flowing of the resin during molding, it is important to select the base layer in consideration of elasticity, elongation and the like at high temperatures.

The material of the base layer is preferably a polyester resin from the viewpoints of thermal resistance and elasticity at high temperatures. Examples of the polyester resin include a polyethylene terephthalate resin, a polyethylene naphthalate resin, and a polybutyrene terephthalate resin, and copolymers and modified resins thereof.

The base layer is preferably a layer formed by shaping a polyester resin into a sheet shape. The base layer is more preferably a polyester film, and, from the viewpoint of shape changeability to conform to the mold, the base layer is preferably a biaxially-stretched polyester film.

The thickness of the base layer is not particularly limited, and is preferably from 5 μm to 100 μm, and more preferably from 10 μm to 70 μm. When the thickness is 5 μm or more, the release sheet has excellent handleability, and there is a tendency that wrinkles scarcely occur. When the thickness is 100 μm or less, the shape changeability to conform to the mold at the time of molding is excellent, and there is a tendency that occurrence of wrinkles or the like on the molded semiconductor package is reduced.

[Other Structural Features]

The base layer is a layer that contacts a surface of a mold, and a larger peeling force may be necessary in order to peel the release sheet from the mold, depending on the nature of the material used. When such a material that is difficult to peel from the mold is used in the base layer, it is preferable to design the release sheet so as to facilitate peeling of the release sheet from the mold. For example, surface treatment such as emboss processing (for example, satin finishing or matte finishing) may be performed on a face of the base layer opposite from a face contacting the specific release layer, i.e., on the mold-side face of the base layer, or another release layer (a second release layer) may be newly provided, in order to enhance the releasability from the mold. The material of the second release layer is not particularly limited as long as the material has thermal resistance, releasability from the mold, and the like, and the material of the second release layer may be the same material as that of the specific release layer. The thickness of the second release layer is not particularly limited, and is preferably from 0.1 μm to 100 μm.

Further, if necessary, a layer such as a coloring layer, an antistatic layer or an anchoring enhancing layer for the specific release layer or the second release layer may be provided, for example, between the specific release layer and the base layer or between the base layer and the second release layer.

<Method of Manufacturing Release Sheet>

The release sheet can be prepared using a known method. For example, the release sheet may be prepared by, for example, applying a composition for forming a release layer, which composition includes particles in an amount of 5% by volume to 65% by volume with respect to the total solids content, to one side of the base layer, followed by drying. The composition for forming a release layer may include a resin component, and other components that are optionally added.

[Preparation of Composition for Forming Release Layer]

The method used for preparing the composition for forming a release layer is not particularly limited. For example, a method including dispersing particles in a solvent may be used. Known methods for forming a composition may be used.

The solvent used for preparing the composition for forming a release layer is not particularly limited, and the solvent is preferably an organic solvent in which particles are dispersible, and which is capable of dissolving the resin component. Examples of the organic solvent include toluene, methyl ethyl ketone and ethyl acetate.

[Application and Drying]

The method used for applying the composition for forming a release layer to one side of the base layer is not particularly limited, and know coating methods such as roll coating, bar coating, and kiss coating may be used. The composition for forming a release layer may be applied such that the thickness of the composition layer (release layer) after drying becomes 0.1 μm to 100 μm.

The method used for drying the composition for forming a release layer, which has been applied, is not particularly limited, and known drying methods may be used. For example, a method including drying at 50° C. to 150° C. for 0.1 minutes to 60 minutes may be used.

<Molding of Semiconductor Package>

The release sheet for compression molding may be used for molding a semiconductor package, and, particularly, the release sheet for compression molding can be suitably used for compression molding.

Usual compression molding for a semiconductor package includes disposing a release sheet in a mold of a compression molding apparatus, and making the release sheet conform to the shape of the mold by, for example, vacuum suction. Thereafter, the sealing material for a semiconductor package (for example, an epoxy resin) is placed in the mold, a semiconductor chip is placed thereon, and the mold is pressed while heating to cure the sealing material and thereby obtain a molded semiconductor package. Thereafter, the mold is opened, and the molded semiconductor package is taken out.

As described above, since a release sheet is made to tightly contact with a mold in compression molding, the release sheet is requested to have excellent shape changeability to conform to the shape of the mold. Further improved shape changeability to conform to the mold can be imparted to the release sheet by including a resin having excellent stretchability in the base layer.

When the release sheet for compression molding according to the present specification is placed such that the face of the specific release layer contacts a semiconductor package (molded product) in compression molding of a semiconductor, peeling of the release sheet from the semiconductor package is made easier in the peeling process after molding, the sealing material and the mold can easily be separated from each other without damaging the semiconductor package, the outer appearance of the surface of the molded package has excellent uniformity, flow marks resulting from flow of the sealing material are reduced, and contamination of the surface of the molded package caused by a film material is also reduced.

### EXAMPLES

The invention is specifically described by reference to examples. However, the invention is not limited to these examples.

### Example 1

100 parts by mass of an acrylic resin (WS-023, available from Teikoku Kagaku Sangyo K.K.), 10 parts by mass of CORONATE L (tradename; available from Nippon Polyurethane Industry Ltd.) as a crosslinking agent and 10 parts by mass of TAFTIC FH-S010 (tradename; acrylic particles having an average particle diameter of 10 μm, available from Toyobo Co., Ltd.) as particles (C) were added to toluene to prepare a composition for forming a release layer, which is a toluene solution having a solids content of 15% by mass.

A biaxially-stretched polyethylene terephthalate film having a thickness of 25 μm (S-25 available from Unitika Ltd.) as a base layer was subjected to corona treatment. Thereafter, the composition for forming a release layer was applied to one side of the biaxially-stretched polyethylene terephthalate film using a roll coater and dried to have an average thickness after drying of 10 μm, thereby forming a release layer. A release sheet was obtained in this manner.

The content ratio of the particles (C) in the release layer of the obtained release sheet was measured based on observation of a cross-section under a SEM, and the content ratio was found to be 10% by volume.

[Measurement of Properties of Release Sheet]

The release sheet was placed on the upper part of the mold for compression molding, in which a semiconductor bare chip had been set in the lower part of the mold. The release sheet was fixed by vacuum, and the parts of the mold were clamped together to mold (by compression) a sealing material (tradename CEL-9750ZHF10, available from Hitachi Chemical Company Ltd.), thereby obtaining a semiconductor package. The mold temperature was 180° C., the molding pressure was 6.86 MPa (70 kgf/cm²), and the molding time was 180 seconds.

The releasability of the release sheet from the sealing material after molding, the uniformity of the outer appearance of the surface of the molded semiconductor package (the presence or absence of flow marks resulting from flow of the sealing material), and the presence or absence of drop-off of the particles (C) onto the surface of the molded semiconductor package (the presence or absence of contamination) were evaluated in the following manner. The results of the evaluations are indicated in Tables 1 and 2.

(Evaluation of Releasability from Sealing Material after Molding)

The peeling force was measured in a peeling test with a peeling angle of 180° and a peeling velocity of 300 mm/minute, and used as an indicator of the releasability of the release sheet from the sealing material after molding. Evaluation was performed according to the following criteria.

A: less than 0.5 N/50 mm

B: from 0.5 N/50 mm to less than 5.0 N/50 mm

C: 5.0 N/50 mm or more

(Evaluation of Outer Appearance of Surface of Semiconductor Package)

The presence or absence of flow marks resulting from flow of the sealing material on the surface of the semiconductor package was observed by eyes and under an optical microscope (at 100-fold magnification). Evaluation was performed according to the following criteria.

A: No flow marks are observed in both of the eye observation and the microscopic observation

B: No flow marks are observed in the eye observation, but slight flow marks are observed in the microscopic observation

C: Flow marks are observed in both of the eye observation and the microscopic observation

(Presence or Absence of Drop-Off of Particles (C) onto Surface of Semiconductor Package)

The presence or absence of drop-off of the particles (C) onto the surface of the semiconductor package was observed by eyes and under an optical microscope (at 100-fold magnification). Evaluation was performed according to the following criteria.

A: Drop-off of the particles (C) is observed in neither the eye observation nor the microscopic observation

B: Drop-off of the particles (C) is observed in the eye observation while slight drop-off of the particles (C) is observed in the microscopic observation

C: Drop-off of the particles (C) is observed in both of the eye observation and the microscopic observation

### Examples 2 to 9 and Comparative Examples 1 to 3

Release sheets of Examples 2 to 9 and Comparative Examples 1 to 3 were prepared in the same manner as that in Example 1, except that at least one of the thickness of the A layer after drying, the presence or absence of the release layer, or the type or content ratio of the particles (C) was changed as indicated in the following Tables 1 and 2. The results of the evaluations are indicated in Tables 1 and 2.

The particles (C) referred to in Tables 1 and 2 are as follows:

TAFTIC FH-S015 (tradename, available from Toyobo Co., Ltd.)

TAFTIC FH-S020 (tradename, available from Toyobo Co., Ltd.)

TAFTIC FH-S050 (tradename, available from Toyobo Co., Ltd.)

SX-500H (tradename, available from Soken Chemical & Engineering Co., Ltd.)

TAFTIC ASF-7 (tradename, available from Toyobo Co., Ltd.)

E606 (tradename, available from Dow Corning Toray Co., Ltd.)

BM30X-12 (tradename, available from Sekisui Plastics Co., Ltd.)

HPS-3500 (tradename, available from Toagosei Co., Ltd.)

In Tables 1 and 2, “PMMA” refers to poly(methyl methacrylate), and “PMBA” refers to poly(butyl methacrylate). In Table 2, “-” indicates that the ingredient is not used, or that the property cannot be detected.

TABLE 1

| | | Example 1 | Example 2 | Example 3 | Example 4 | Example 5 | Example 6 |
|---|---|---|---|---|---|---|---|
| Particles | Tradename | TAFTIC | TAFTIC | TAFTIC | TAFTIC | SX-500H | TAFTIC |
| (C) | | FH-S010 | FH-S015 | FH-S020 | FH-S050 | | ASF-7 |
| | Material | Acrylic (PMMA) | Acrylic (PMMA) | Acrylic (PMMA) | Acrylic (PMMA) | Polystyrene | Polyacrylonitrile |
| | Average Particle | 10 | 15 | 20 | 50 | 5 | 7 |
| | Diameter (μm) | | | | | | |
| | Content Ratio | 10 | 20 | 60 | 40 | 10 | 10 |
| | (% by Vol.) | | | | | | |

| | | | | | | |
|---|---|---|---|---|---|---|
| Thickness of Release Layer after | 10 | 15 | 20 | 50 | 5 | 10 |
| Drying (μm) | | | | | | |
| Releasability after Molding | A | A | A | A | A | A |
| Uniformity of Outer Appearance | B | A | A | B | B | B |
| Presence or Absence of Drop-off | A | A | B | A | A | A |
| of Particles (C) | | | | | | |

TABLE 2

| | | | | | Comparative | Comparative | Comparative |
|---|---|---|---|---|---|---|---|
| | | Example 7 | Example 8 | Example 9 | Example 1 | Example 2 | Example 3 |
| Particles | Tradename | E606 | BM30X-12 | HPS-3500 | Release | Not Added | TAFTIC |
| (C) | | | | | Layer Was | | FH-S020 |
| | Material | Silicone | Acrylic (PMBA) | Silica | Not | — | Acrylic (PMMA) |
| | Average Particle | 2 | 12 | 3.5 | Provided | — | 20 |
| | Diameter (μm) | | | | | | |
| | Content Ratio | 10 | 10 | 15 | | — | 70 |
| | (% by Vol.) | | | | | | |

| | | | | | | |
|---|---|---|---|---|---|---|
| Thickness of Release Layer after | 5 | 15 | 5 | | 3 | 20 |
| Drying (μm) | | | | | | |
| Releasability after Molding | A | A | B | C | A | A |
| Uniformity of Outer Appearance | B | B | B | — | C | A |
| Presence or Absence of Drop-off | A | A | B | — | A | C |
| of Particles (C) | | | | | | |

As shown in Tables 1 and 2, the release sheets of Examples 1 to 9 exhibited excellent releasability from the sealing material after molding, and has excellent uniformity of the outer appearance of the surface of the molded package, and drop-off of the particles (C) onto the surface of the molded package was reduced.

Although not shown in Tables 1 and 2, a release sheet was prepared and evaluated in the same manner as that in Examples 1 except that the content ratio of the particles (C) was set to 1% by volume, as a result of which flow marks were observed in both of the eye observation and the microscopic observation, and sufficient uniformity of the outer appearance of the surface was not obtained.

In Comparative Example 1, in which a release layer was not provided, the sealing material and the release sheet could not be separated from each other after molding. In Comparative Example 2, in which a release layer free of particles was used, the outer appearance of the surface of the molded package was non-uniform, and flow marks resulting from flow of the sealing material was observed. In Comparative Example 3, in which the content ratio of particles was above 65% by volume, drop-off of the particles was observed.

As described above, use of the release sheet according to embodiments of the invention makes it possible to provide a release film which enables easy release of the sealing material from the mold without damaging the semiconductor package when the semiconductor package is resin-molded, has excellent uniformity of the outer appearance of the surface of the molded package, and enables reduction of contamination of the surface of the molded package caused by a film material.

1. A release sheet for semiconductor compression molding, the release sheet comprising:
a release layer comprising particles; and
a base layer,
wherein a content ratio of the particles in the release layer is from 5% by volume to 65% by volume.

2. The release sheet for semiconductor compression molding according to claim 1, wherein the particles have an average particle diameter of from 1 μm to 55 μm.

3. The release sheet for semiconductor compression molding according to claim 1, wherein the particles comprise resin particles.

4. The release sheet for semiconductor compression molding according to claim 3, wherein the resin particles comprise at least one selected from the group consisting of an acrylic resin, a polyolefin resin, a polystyrene resin, a polyacrylonitrile resin, and a silicone resin.

5. The release sheet for semiconductor compression molding according to claim 1, wherein the base layer comprises a polyester film.

6. A semiconductor package molded using the release sheet for semiconductor compression molding according to claim 1.

7. A method of producing a semiconductor package, the method comprising:
molding a semiconductor package using a release sheet by compression molding,
wherein the release sheet comprises:
a release layer comprising particles; and
a base layer,
wherein a content ratio of the particles in the release layer is from 5% by volume to 65% by volume.

8. The method according to claim 7, wherein the particles have an average particle diameter of from 1 μm to 55 μm.

9. The method according to claim 7, wherein the particles comprise resin particles.

10. The method according to claim 9, wherein the resin particles comprise at least one selected from the group consisting of an acrylic resin, a polyolefin resin, a polystyrene resin, a polyacrylonitrile resin, and a silicone resin.

11. The method according to claim 7, wherein the base layer comprises a polyester film.

12. The method according to claim 7, wherein the molding comprises:
disposing the release sheet in a mold of a compression molding apparatus in such a manner that the release layer contacts the semiconductor package to be formed.

13. The method according to claim 12, wherein, after the release sheet has been disposed in the mold, the release sheet is made conform to the shape of the mold by vacuum suction.
